(19) United States
(12) Patent Application Publication
(10) Pub. No.: US 2025/0174849 A1
(43) Pub. Date: May 29, 2025

(54) CLAD TERMINAL EMBEDDED IN A SEPARATOR LAYER OF A BATTERY CELL FOR MONITORING VOLTAGE AND IMPEDANCE

(71) Applicant: GM GLOBAL TECHNOLOGY OPERATIONS LLC, Detroit, MI (US)

(72) Inventors: Qili SU, Shanghai (CN); Meiyuan WU, Shanghai (CN); Zhe LI, Shanghai (CN); Yong LU, Shanghai (CN); Haijing LIU, Shanghai (CN)

(21) Appl. No.: 18/410,275

(22) Filed: Jan. 11, 2024

(30) Foreign Application Priority Data
Nov. 29, 2023 (CN) 202311642198.9

(51) Int. Cl. H01M 50/569; G01R 31/3835; G01R 31/385; H01M 10/0585; H01M 50/46; H01M 50/463; H01M 50/489; H01M 50/534

(52) U.S. Cl. CPC H01M 50/569; H01M 10/0585; H01M 50/46; H01M 50/463; H01M 50/489; H01M 50/534; G01R 31/3835; G01R 31/385

(57) ABSTRACT

A battery cell includes a cathode electrode including a cathode active material layer and a cathode current collector. An anode electrode includes an anode active material layer and an anode current collector. A solid electrolyte layer is arranged between the cathode active material layer and the anode active material layer. The cathode electrode and the anode electrode exchange lithium ions. A clad terminal comprises a first metal layer and a second metal layer and includes a first portion arranged in the solid electrolyte layer and a second portion extending from the solid electrolyte layer.

### CROSS-REFERENCE TO RELATED APPLICATIONS

This application claims the benefit of Chinese Patent Application No. 202311642198.9, filed on Nov. 29, 2023. The entire disclosure of the application referenced above is incorporated herein by reference.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to battery cells, and more particularly to a clad terminal embedded in a separator of a battery cell.

Electric vehicles (EVs) such as battery electric vehicles (BEVs), hybrid vehicles, and/or fuel cell vehicles include one or more electric machines and a battery system including one or more battery cells, modules, and/or packs. A power control system is used to control charging and/or discharging of the battery system during charging and/or driving.

Battery cells include one or more cathode electrodes, anode electrodes, and separators. The cathode electrodes include a cathode active material layer (including cathode active material) arranged on a cathode current collector. The anode electrodes include an anode active material layer (including anode active material) arranged on an anode current collector.

### SUMMARY

A battery cell includes a cathode electrode including a cathode active material layer and a cathode current collector. An anode electrode includes an anode active material layer and an anode current collector. A solid electrolyte layer is arranged between the cathode active material layer and the anode active material layer. The cathode electrode and the anode electrode exchange lithium ions. A clad terminal comprises a first metal layer and a second metal layer and includes a first portion arranged in the solid electrolyte layer and a second portion extending from the solid electrolyte layer.

In other features, the cathode electrode and the clad terminal are charged to convert the first metal layer to a lithium-metal alloy. The first metal layer of the clad terminal is arranged in the solid electrolyte layer. The first metal layer is selected from a group consisting of aluminum (Al), tin (Sn), indium (In), gold (Au), zinc (Zn), bismuth (Bi), and alloys thereof. The second metal layer is selected from a group consisting of stainless steel, copper, nickel, iron, titanium, and alloys thereof.

In other features, the solid electrolyte layer includes a first solid electrolyte portion and a second solid electrolyte portion, the clad terminal is embedded in the first solid electrolyte portion, and the first solid electrolyte portion and the clad terminal are embedded in the second solid electrolyte portion.

In other features, the clad terminal is densified in the first solid electrolyte portion prior to densification of the first solid electrolyte portion and the clad terminal with at least one of the second solid electrolyte portion, the cathode electrode, and the anode electrode. The clad terminal is densified in the first solid electrolyte portion prior to densification of the first solid electrolyte portion and the clad terminal between the cathode electrode and the second solid electrolyte portion. The first solid electrolyte portion contacts the cathode electrode.

In other features, a thickness Tc of the clad terminal is in a range from 10 μm to 50 μm, a thickness T1 of the first solid electrolyte portion is in a range from 15 μm to 60 μm, and a thickness T2 of the second solid electrolyte portion is in a range from 20 μm to 70 μm. The battery cell comprises an all-solid-state battery (ASSB) cell. The first metal layer and the second metal layer comprise foil.

A method for manufacturing a battery cell includes arranging a first portion of a clad terminal including a first metal layer and a second metal layer in a solid electrolyte layer, wherein a second portion of the clad terminal extends from the solid electrolyte layer; arranging the solid electrolyte layer and the clad terminal between a cathode electrode and an anode electrode, wherein the cathode electrode and the anode electrode exchange lithium ions; and densifying the cathode electrode, the anode electrode, the solid electrolyte layer, and the clad terminal.

In other features, the method includes charging the cathode electrode relative to the clad terminal to convert the first metal layer to a lithium-metal alloy. Prior to arranging the solid electrolyte layer and the clad terminal between the cathode electrode and the anode electrode, densifying the solid electrolyte layer and the clad terminal. The solid electrolyte layer and the clad terminal are densified at a pressure less than 100 MPa for a period less than 1 min. The cathode electrode, the anode electrode, the solid electrolyte layer, and the clad terminal are densified at a pressure in a range from 300 to 400 MPa for a predetermined period in a range from 1 to 10 minutes.

In other features, the first metal layer of the clad terminal is arranged in the solid electrolyte layer perpendicular to a cathode active material layer of the cathode electrode. The battery cell comprises an all-solid-state battery, the first metal layer is selected from a group consisting of aluminum (Al), tin (Sn), indium (In), gold (Au), zinc (Zn), bismuth (Bi), and alloys thereof, and the second metal layer is selected from a group consisting of stainless steel, copper, nickel, iron, titanium, and alloys thereof.

In other features, the solid electrolyte layer includes a first solid electrolyte portion and a second solid electrolyte portion. The clad terminal is arranged in the first solid electrolyte portion, and the first solid electrolyte portion and the clad terminal are arranged in the second solid electrolyte portion.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross sectional view of an example of a battery cell including a clad terminal embedded in a separator layer between a pair of anode and cathode electrodes of a battery cell according to the present disclosure;

FIG. 2 is a side cross sectional view of an example of an anode electrode, a cathode electrode, and a separator layer including a clad terminal according to the present disclosure;

FIG. 3A is a flowchart of an example of an example of a method for embedding the clad terminal in the separator layer according to the present disclosure;

FIGS. 3B and 3C illustrate an example of an activation method for a first metal layer of the clad terminal according to the present disclosure;

FIGS. 4A to 4C are side cross sectional views of an example of clad terminals embedded in a solid electrolyte layer according to the present disclosure;

FIG. 5 is a side view of an example of a press including dies configured to densify a cathode electrode, an anode electrode, and a separator layer including a clad terminal according to the present disclosure;

FIGS. 6A and 6B are plan views illustrating an example of pouch battery cells with flexible clad foil and/or a rigid clad terminal extending from a pouch enclosure according to the present disclosure;

FIGS. 7A and 7B are graphs illustrating an example of voltage as a function of capacity during charging and discharging according to the present disclosure; and

FIGS. 8A to 8C are graphs illustrating an example of impedance for a charged state, a discharged state, and a middle state between the charged state and the discharged state according to the present disclosure.

In the drawings, reference numbers may be reused to identify similar and/or identical elements.

### DETAILED DESCRIPTION

While battery cells according to the present disclosure are shown in the context of electric vehicles and/or testing of battery cells for electric vehicles, the battery cells can be used in stationary applications and/or other applications.

During development of all-solid-state batteries (ASSBs), the voltage potential and/or impedance contribution of the anode electrodes and cathode electrodes are important for the design of ASSBs. It is not possible to monitor the voltage potential and/or impedance contribution of the cathode electrode and the anode electrode independently using the existing connections provided by the battery terminals. It is important to characterize the performance of the anode electrodes and cathode electrodes separately and simultaneously during cycling of the battery cells of the ASSBs.

An in-situ monitoring tool according to the present disclosure incorporates a clad terminal such as clad foil as reference electrode in a separator layer (e.g., a solid electrolyte layer) of all-solid-state battery (ASSB). The clad terminal includes a first metal layer (e.g., an aluminum layer) and a second metal layer. The clad terminal is lithiated in-situ to convert the first metal layer into a lithium-metal alloy (e.g., lithium-aluminum alloy) through an initial electrochemical reaction between the cathode electrode and the first metal layer.

In some examples, the lithium-metal alloy of the first metal layer has low reactivity with a solid electrolyte (e.g., a sulfide solid electrolyte) and a flat potential platform (0.38V) within the all-solid-state battery. The lithium-metal alloy of the first metal layer serves as a reference electrode. In addition, the second metal layer (e.g., a copper layer) of the clad terminal provides high electronic conductivity as a current lead. The clad terminal can be used to monitor voltage potential and/or impedance in-situ during operation of the ASSB.

As can be appreciated, the clad terminal can be used for test battery cells and/or production battery cells to allow monitoring during testing and/or during operation in a vehicle. While the example battery cells set forth below include a battery cell with a single clad terminal, one or more additional clad terminals can be used in the battery cell to monitor other pairs of other anode electrode(s) or cathode electrode(s).

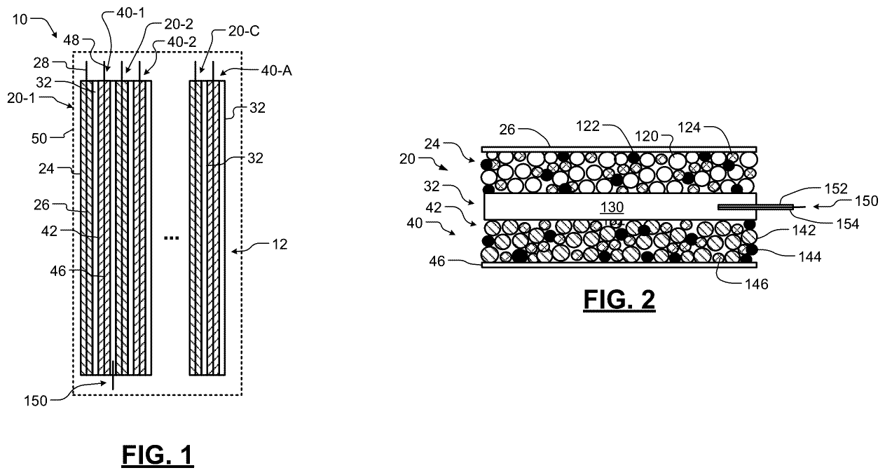

Referring now to FIG. 1, a battery cell 10 includes C cathode electrodes 20, A anode electrodes 40, and S separators 32 arranged in a predetermined sequence in a battery cell stack 12, where C, S and A are integers greater than zero. The C cathode electrodes 20-1, 20-2, . . . , and 20-C include cathode active material layers 24 arranged on one or both sides of a cathode current collector 26.

During charging/discharging, the A anode electrodes 40 and the C cathode electrodes 20 exchange lithium ions. The A anode electrodes 40-1, 40-2, . . . , and 40-A include anode active material layers 42 arranged on one or both sides of the anode current collectors 46. In some examples, the cathode active material layers 24 and/or the anode active material layers 42 comprise coatings including one or more active materials, one or more conductive additives, and/or one or more binder materials that are applied to the current collectors (e.g., using a wet or dry roll-to-roll process). In some examples, the pair(s) of anode electrode(s) and cathode electrode(s) with the separator including the clad terminal are manufactured in a separate process and inserted in the battery cell stack.

In some examples, the cathode current collector 26 and/or the anode current collector 46 comprises metal foil, metal mesh, perforated metal, 3 dimensional (3D) metal foam, and/or expanded metal. In some examples, the current collectors are made of one or more materials selected from a group consisting of copper, stainless steel, brass, bronze, zinc, aluminum, and/or alloys thereof. External tabs 28 and 48 are connected to the current collectors of the cathode electrodes and anode electrodes, respectively, and can be arranged on the same or different sides of the battery cell stack 12. The external tabs 28 and 48 are connected to terminals of the battery cells. At least one of the separators 32 includes a clad terminal 150 as will be described further below.

Referring now to FIG. 2, the cathode active material layer 24 comprises cathode active material 120, a conductive additive 122, and/or a solid electrolyte 124. The anode active material layer 42 comprises anode active material 142, a conductive additive 144, and a solid electrolyte 146. The separator 32 comprises a solid electrolyte layer 130 including a clad terminal 150. A first portion of the clad terminal is embedded in the separator 32 and a second portion extends from the separator 32. The clad terminal includes a first metal layer 152 attached to a second metal layer 154. In some examples, the clad terminal 150 comprises a wire, a thin film, a foil, and a mesh.

In some examples, the first metal layer 152 is selected from a group consisting of aluminum (Al), tin (Sn), indium (In), gold (Au), zinc (Zn), bismuth (Bi), and alloys thereof. In some examples, the first metal layer 152 (facing or perpendicular to the cathode electrode) forms a lithium-metal (Li-M) alloy and has low reactivity with sulfide electrolyte and a stable lithium-alloy chemical potential within the battery cell. For example, the metal can include aluminum (Al) and the Li-Al alloy includes LiₓAl (where 0<x≤0.8). The Li—Al alloy shows a stable potential platform at 0.38V vs. Li/Li+. Other metals have different potentials vs. Li/Li+. For example, LiₓSn has a potential of 0.660 vs. Li/Li+ (where 0.4≤x≤0.7). For example, LiₓIn has a potential of 0.62 vs. Li/Li+. For example, LiₓAu has a potential of 0.1 vs. Li/Li+. For example, LiₓZn has a potential of 0.256 vs. Li/Li+ (where 0.4≤x≤0.5). For example, LiₓBi has a potential of 0.828 vs. Li/Li+ (where 0<x≤1).

In some examples, the lithiation capacity of the Li-M alloy is relatively low (<1 μAh). In other words, the clad terminal 150 can be used for thousands of cycles. The Li-M alloying may cause moderate volume expansion of the first metal layer 152 that will have minimal impact on the solid electrolyte layer. The clad terminal 150 has high mechanical stability without deformation under high pressure. The second metal layer 154 (facing or perpendicular to the anode electrode) provides high electronic conductivity that ensures an accurate potential monitoring.

In some examples, the second metal layer 154 has a thickness in a range from 2 μm to 20 μm. In some examples, the second metal layer 154 is selected from a group consisting of stainless steel, copper, nickel, iron, titanium, and alloys thereof.

In some examples, the cathode active material 120 comprises LiNiₓMn_{y}Co_{1-x-y} O₂ (NMC), the conductive additive 122 comprises SuperP, and the solid electrolyte 124 comprises argyrodite-type solid electrolyte Li₆PS₅Cl (LPSCl). In some examples, the anode active material 142 comprises silicon, the conductive additive 144 comprises SuperP, and the solid electrolyte 146 comprises LPSCl.

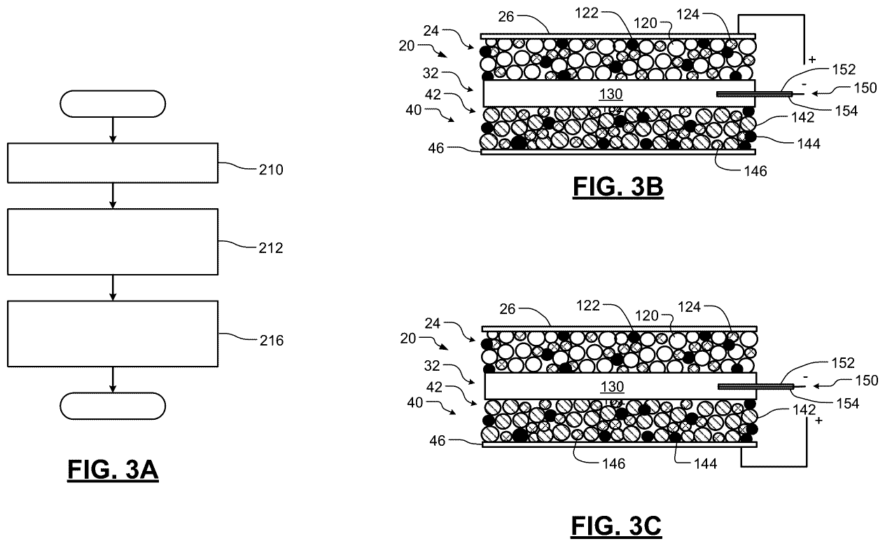

Referring now to FIG. 3A, a method for manufacturing the battery cell includes embedding and densifying a clad terminal (including the first metal layer and the second metal layer) in a solid electrolyte at 210. In some examples, the clad terminal is embedded and densified within the solid electrolyte by pressing the solid electrolyte and the clad terminal with a pressure less than 100 MPa for a period less than 1 min. This preliminary densification step may be used to immobilize the clad terminal inside the solid electrolyte and prevent contact with the cathode electrode or the anode electrode.

At 212, a cathode electrode, the solid electrolyte with the clad terminal, and an anode electrode are densified. In some examples, the cathode electrode, the solid electrolyte with the clad terminal, and the anode electrode are densified in a single densification step or two or more densification steps. In some examples, the cathode electrode, the solid electrolyte with the clad terminal, and the anode electrode are densified at a pressure in a range from 300 to 400 MPa (e.g., 360 MPa) for a predetermined period in a range from 1 to 10 minutes (e.g., greater than 2 min).

At 216, a lithium metal alloy is formed in situ by charging the cathode electrode (and/or anode electrode) relative to the clad terminal 150. The clad terminal 150 can be used to monitor voltage potential and/or impedance of the anode electrode, the cathode electrode, and/or both the anode electrode and the cathode electrode while operating at different states of charge or discharge.

Referring now to FIG. 3B, in some examples, in-situ forming of the Li-M alloy is performed by charging the cathode electrode 20 relative to the clad terminal 150 with low current (<1 μA, <1 hour). In some examples, in-situ forming also includes charging the anode electrode 40 relative to the clad terminal 150 with low current (<1 μA, <1 hour) as shown in FIG. 3C. Charging of the anode electrode relative to the clad terminal can be used to a uniform Li—Al alloy within battery, so it can test anode/clad foil impedance and potential more accurately. If the battery (cathode electrode vs. anode electrode) is higher than zero SOC %, there is some active lithium in anode electrode, the clad foil can be in-situ forming the Li—Al alloy.

When activating the clad terminal 150, the cathode electrode 20 is connected to a charger as the positive terminal and the clad terminal 150 as the negative terminal as shown in FIG. 3B. The cathode electrode 20 and the clad terminal 150 are charged with a current (<1 μA) to a stable voltage when the Li-alloying has been formed. The current (<1 μA) is very small and there is little capacity loss in cathode electrode so chemical potential of cathode electrode is stable. The potential of Al will be stable when Li—Al alloy is forming. The charging voltage of cathode electrode and clad terminal is the chemical potential of cathode minus the potential of Li—Al alloy. The charge time is less than 0.5 hours.

In some examples, the anode electrode 40 is connected to the charger as the positive terminal and the clad terminal 150 as the negative terminal as shown in FIG. 3C. The anode electrode 20 and the clad terminal 150 are charged with a current (e.g., <1 μA) for a predetermined period (e.g., <0.5 hours). The Li-M alloy is activated and the clad terminal 150 can be used for potential monitoring. If the reference potential fails to monitor the solid-state battery, the charging protocol above is repeated.

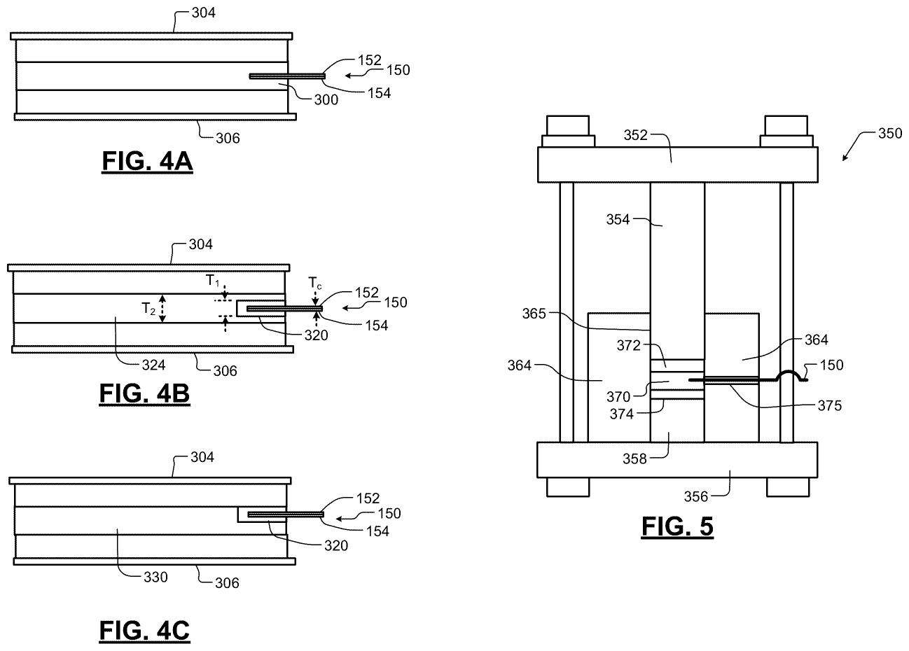

Referring now to FIGS. 4A to 4C, examples of densification of the clad terminal 150 in a solid electrolyte layer are shown. In FIG. 4A, the clad terminal 150 is densified near a middle region of a solid electrolyte layer 300 (e.g., so that the clad terminal 150 is spaced from a cathode electrode 304 and an anode electrode 306 to avoid short circuits). Then, the clad terminal 150 and the solid electrolyte layer 173 are densified with the cathode electrode 304 and the anode electrode 306. Alternately, the clad terminal 150 and the solid electrolyte layer 300 are densified with the cathode electrode 304 and the anode electrode 306 in a single densification step.

In FIG. 4B, the clad terminal 150 is densified near a middle region of a first solid electrolyte layer 320 (e.g., spaced from the cathode electrode 304 and the anode electrode 306). Then, the clad terminal 150 and the first solid electrolyte layer 320 are embedded in a second solid electrolyte layer 324 near a middle region of the second solid electrolyte layer 324 (e.g., spaced from the cathode electrode 304 and the anode electrode 306).

In some examples, the second solid electrolyte layer 324 is densified around the clad terminal 150 and the first solid electrolyte layer 320 and one or more subsequent densification steps are used to densify the cathode electrode 304 and/or the anode electrode 306 around the second solid electrolyte layer 324. Alternately, the cathode electrode 304 and/or the anode electrode 306, the second solid electrolyte layer 324, and the clad terminal 150 and the first solid electrolyte layer 320 are densified together in a single or combined densification step. This approach can be used if the position of the clad terminal can be maintained centered in the solid electrolyte layer (avoiding shorting with the anode or cathode electrodes). The first solid electrolyte layer 320 can be made of the same type of solid electrolyte as the second solid electrolyte layer 324 or the first solid electrolyte layer 320 and the second solid electrolyte layer 324 can be made of different types of solid electrolytes.

The solid electrolyte material used for the first solid electrolyte layer 320 is selected to have high reductive stability and compatibility with the first metal layer 152 (e.g., the Li-M alloy). As a result, the Li-M alloy will have a higher durability due to its low reactivity with the first solid electrolyte layer 320. For example, the first solid electrolyte layer 320 may comprise sulfide solid electrolyte such as Li₇P₃S₁₁. As can be appreciated, the clad terminal 150 and the first solid electrolyte layer 320 can be embedded in different types of solid electrolyte and/or battery cell chemistries. In some examples, a thickness T₂ of the second solid electrolyte layer 324 is greater than a thickness T₁ of the first solid electrolyte layer 320. In some examples, the thickness of the first solid electrolyte layer 320 is greater than the thickness T_{c} of the clad terminal 150.

In some examples, the thickness T_{c} is in a range from 10 μm to 50 μm. In some examples, the thickness T1 is in a range from 15 μm to 60 μm. In some examples, the thickness T2 is in a range from 20 μm to 70 μm.

In FIG. 4C, the clad terminal 150 is densified in the first solid electrolyte layer 320 as described above. Then the clad terminal 150 and the first solid electrolyte layer 320 are densified between a cathode electrode 186 and a second solid electrolyte layer 330. The clad terminal 150 can be arranged along the cathode active material layer of the cathode electrode 304 since the first solid electrolyte 182 insulates the clad terminal 150.

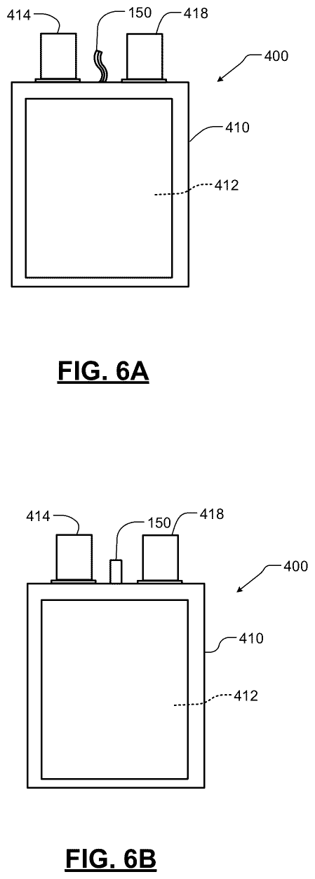

Referring now to FIG. 5, an example of a press 350 for manufacturing a battery cell including a cathode electrode, an anode electrode, and a separator with an embedded clad terminal/foil is shown. In some examples, a pellet cell format is used. An upper press 352 is connected to an upper die 354 and a lower press 356 is connected to a lower die 358. In some examples, the upper die 354, the lower die 358, the upper press 352 and the lower press 356 are made of stainless steel. A mold 364 includes an inner cavity 365 having a diameter slightly larger than a diameter of the battery cell and configured to removably receive the upper die 354 and the lower die 358. In some examples, the mold 364 is made of a polymer such as polyether ether ketone (PEEK) or another suitable polymer.

An anode electrode 374 (including an anode current collector and anode active material) is arranged in the inner cavity 365 on the lower die 358. Some of the solid electrolyte material corresponding to a solid electrolyte layer 370 is arranged on the anode electrode 374 and the clad terminal 150 is inserted through a hole 375 in the mold 364. The remainder of the solid electrolyte material corresponding to the solid electrolyte layer 370 is arranged on the clad terminal and the remaining material of the solid electrolyte layer 370. A cathode electrode 372 (including cathode active material and a cathode current collector) are arranged on the solid electrolyte layer 370. The press 350 applies pressure and/or heat to densify the layers.

Referring now to FIGS. 6A and 6B, a pouch cell 400 includes a pouch enclosure 410 including a battery cell stack 412. Terminals 414 and 418 extend from the pouch enclosure 410 and are electrically connected to external tabs that are connected to anode and cathode current collectors, respectively. At least one separator includes the clad terminal 150 embedded therein. The at least one separator is arranged between a cathode electrode and an anode electrode as described above. In FIG. 6A, the clad terminal 150 is flexible and is made of foil. In FIG. 6B, the clad terminal is rigid.

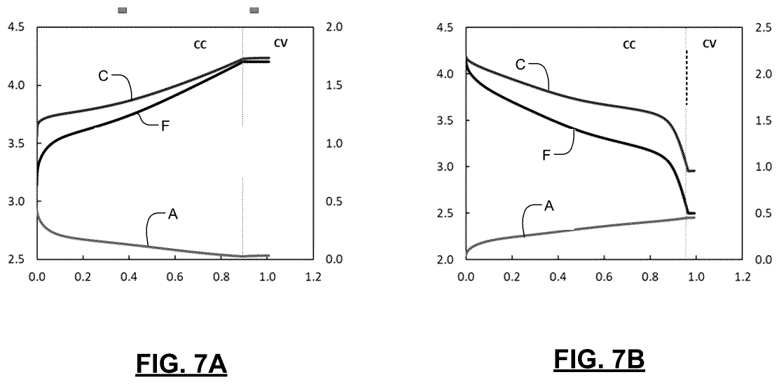

Referring now to FIGS. 7A and 7B, the clad terminal allows voltage monitoring of the cathode electrode C, the anode electrode A, or both the anode electrode and the cathode electrode F (a sum of the cathode electrode and the anode electrode). FIG. 7A shows voltage as a function of capacity for a battery cell during charging to 4.2V using continuous current/continuous voltage (cc-cv) at a rate of 0.5C. FIG. 7B shows voltage as a function of capacity for a battery cell during discharge from over 4V to 2.5V using continuous current (cc) at a rate of 0.5C and a temperature of 25° C.

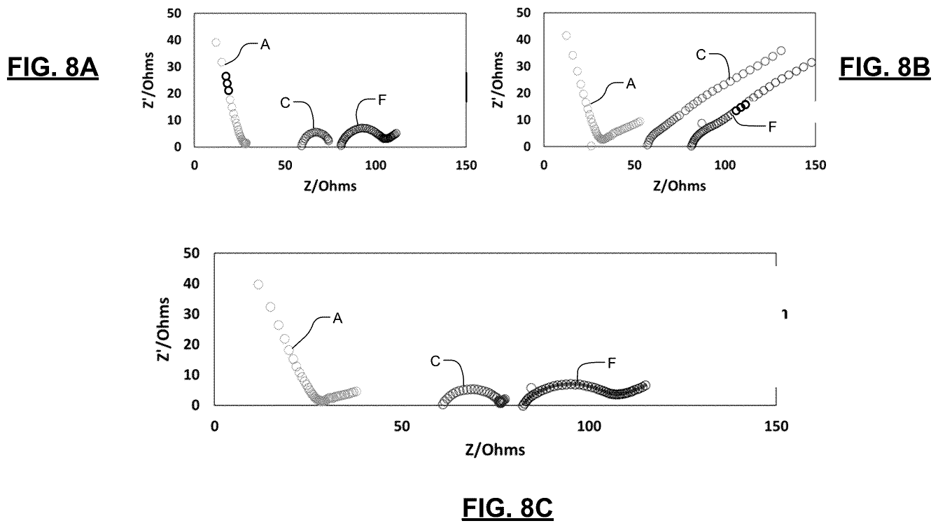

Referring now to FIGS. 8A to 8C, impedance monitoring of the cathode electrode C, the anode electrode A, or both the anode electrode and the cathode electrode Fare shown during a charged state at 4.2V (FIG. 8A), a discharged state at 2.6V (FIG. 8B), and other voltage levels such as 3.4V (FIG. 8C) over a frequency range from 100 kHz to 1 Hz (matched).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

What is claimed is:

1. A battery cell comprising:
a cathode electrode including a cathode active material layer and a cathode current collector;
an anode electrode including an anode active material layer and an anode current collector;
a solid electrolyte layer arranged between the cathode active material layer and the anode active material layer, wherein the cathode electrode and the anode electrode exchange lithium ions; and
a clad terminal comprising a first metal layer and a second metal layer and including a first portion arranged in the solid electrolyte layer and a second portion extending from the solid electrolyte layer.

2. The battery cell of claim 1, wherein the cathode electrode and the clad terminal are charged to convert the first metal layer to a lithium-metal alloy.

3. The battery cell of claim 1, wherein the first metal layer of the clad terminal is arranged in the solid electrolyte layer.

4. The battery cell of claim 3, wherein the first metal layer is selected from a group consisting of aluminum (Al), tin (Sn), indium (In), gold (Au), zinc (Zn), bismuth (Bi), and alloys thereof.

5. The battery cell of claim 3, wherein the second metal layer is selected from a group consisting of stainless steel, copper, nickel, iron, titanium, and alloys thereof.

6. The battery cell of claim 1, wherein:
the solid electrolyte layer includes a first solid electrolyte portion and a second solid electrolyte portion,
the clad terminal is embedded in the first solid electrolyte portion, and
the first solid electrolyte portion and the clad terminal are embedded in the second solid electrolyte portion.

7. The battery cell of claim 6, wherein the clad terminal is densified in the first solid electrolyte portion prior to densification of the first solid electrolyte portion and the clad terminal with at least one of the second solid electrolyte portion, the cathode electrode, and the anode electrode.

8. The battery cell of claim 6, wherein the clad terminal is densified in the first solid electrolyte portion prior to densification of the first solid electrolyte portion and the clad terminal between the cathode electrode and the second solid electrolyte portion.

9. The battery cell of claim 8, wherein the first solid electrolyte portion contacts the cathode electrode.

10. The battery cell of claim 6, wherein a thickness T_{c} of the clad terminal is in a range from 10 μm to 50 μm, a thickness T₁ of the first solid electrolyte portion is in a range from 15 μm to 60 μm, and a thickness T₂ of the second solid electrolyte portion is in a range from 20 μm to 70 μm.

11. The battery cell of claim 1, wherein the battery cell comprises an all-solid-state battery (ASSB) cell.

12. The battery cell of claim 1, wherein the first metal layer and the second metal layer comprise foil.

13. A method for manufacturing a battery cell comprising:
arranging a first portion of a clad terminal including a first metal layer and a second metal layer in a solid electrolyte layer, wherein a second portion of the clad terminal extends from the solid electrolyte layer;
arranging the solid electrolyte layer and the clad terminal between a cathode electrode and an anode electrode, wherein the cathode electrode and the anode electrode exchange lithium ions; and
densifying the cathode electrode, the anode electrode, the solid electrolyte layer, and the clad terminal.

14. The method of claim 13, further comprising charging the cathode electrode relative to the clad terminal to convert the first metal layer to a lithium-metal alloy.

15. The method of claim 13, further comprising, prior to arranging the solid electrolyte layer and the clad terminal between the cathode electrode and the anode electrode, densifying the solid electrolyte layer and the clad terminal.

16. The method of claim 15, wherein the solid electrolyte layer and the clad terminal are densified at a pressure less than 100 MPa for a period less than 1 min.

17. The method of claim 15, wherein the cathode electrode, the anode electrode, the solid electrolyte layer, and the clad terminal are densified at a pressure in a range from 300 to 400 MPa for a predetermined period in a range from 1 to 10 minutes.

18. The method of claim 13, wherein the first metal layer of the clad terminal is arranged in the solid electrolyte layer perpendicular to a cathode active material layer of the cathode electrode.

19. The method of claim 13, wherein:
the battery cell comprises an all-solid-state battery,
the first metal layer is selected from a group consisting of aluminum (Al), tin (Sn), indium (In), gold (Au), zinc (Zn), bismuth (Bi), and alloys thereof, and
the second metal layer is selected from a group consisting of stainless steel, copper, nickel, iron, titanium, and alloys thereof.

20. The method claim 13, wherein the solid electrolyte layer includes a first solid electrolyte portion and a second solid electrolyte portion, and wherein the clad terminal is arranged in the first solid electrolyte portion, and the first solid electrolyte portion and the clad terminal are arranged in the second solid electrolyte portion.
